(19) United States
(12) Patent Application Publication
(10) Pub. No.: US 2002/0003826 A1
(43) Pub. Date: Jan. 10, 2002

(54) Array type laser diode and manufacturing method thereof

(75) Inventor: Isao Yoneda, Tokyo (JP)

Correspondence Address: YOUNG & THOMPSON, 745 SOUTH 23RD STREET 2ND FLOOR, ARLINGTON, VA, 22202

(73) Assignee: NEC Corporation, Tokyo (JP)

(21) Appl. No.: 09/951,563

(22) Filed: Sep. 14, 2001

Related U.S. Application Data
(62) Division of application No. 09/443,046, filed on Nov. 18, 1999.

(30) Foreign Application Priority Data
Nov. 20, 1998 (JP) 10-346679

(51) Int. Cl. H01S 5/00

(52) U.S. Cl. 372/50

(57) ABSTRACT

An array type laser diode and a manufacturing method thereof, in which positioning markers are not needed at channels except a central channel, are provided. Regardless of the number of channels, the following characteristic can be improved at the same time: the stress lessening characteristic inside laser diodes, the bonding strength at connecting wires, and the heat radiation performance of laser diodes, and the mounting of bonding wires to the laser diodes. At the array type laser diode, regardless of the number of channels, positioning markers are provided only at a central channel and are not provided at plural channels at the both sides of the central channel. And a passive alignment technology is applied to form the array type laser diode. With this, mentioned above characteristics can be achieved.

### BACKGROUND OF THE INVENTION

The present invention relates to an array type laser diode and a manufacturing method thereof, in particular, with which an optical information processing such as optical communication and optical recording is implemented by using a light source such as a laser diode in an optical IC technology.

### DESCRIPTION OF THE RELATED ART

Recently, an optical communication technology used optical fiber has been utilized in order to realize an inter-connection technology. At this optical communication technology used the optical fiber, as a light source for the optical communication, the realization of an optical IC in which plural laser diodes are integrated has been required. There is an array type laser diode, as a representative of the optical IC in which plural laser diodes are integrated.

At a conventional array type laser diode, for applying a passive alignment technology, the cathode side of laser diodes is made to be a bonding surface to a mounting substrate and positioning markers are formed at this bonding surface. And at a mounting substrate side, markers are also provided for the passive alignment technology.

Generally, images are formed by projecting shades of metal parts transmitted through these markers using infrared rays and the alignment position is recognized based on these images. And after the alignment position is recognized, the laser diodes are precisely mounted on a designated position by Au Sn (gold tin) solder.

In this case, in addition to conductive electrodes (cathode electrodes), island shaped dielectric electrodes for stress lessening are formed at the both sides of active layer and a thermal stress applying to the active layer is decreased.

However, when the array type laser diode is constructed by arraying diodes on plural channels, dielectric electrodes and positioning markers are formed on the same surface, and the area of dielectric electrodes is reduced by the area of positioning markers. Therefore, there is a problem that the bonding strength is not enough at the cathode side.

FIG. 1 is a diagram showing a pattern of cathode side electrodes bonding to a mounting substrate at a conventional array type laser diode. FIG. 2 is a diagram showing a pattern of anode side electrodes at the conventional array type laser diode shown in FIG. 1.

As shown in FIG. 1, at the conventional array type laser diode, island shaped dielectric electrodes 14 and positioning markers 12 are formed on the same surface in an array state. And as shown in FIG. 2, on the anode side being the opposite side of the cathode electrodes (bonding surface), positioning marker transmitting windows 42, through which optical images of the positioning markers 12 at the cathode side are transmitted, are provided every laser diode.

At this conventional array type laser diode, the positioning markers 12 can be recognized every channel. And when a laser diode is cut out from a wafer, an arbitrary array can be cut out by eliminating defective channels by checking characteristics beforehand. Therefore, at the case that the yield of the laser diodes is unstable, this conventional method is effective.

However, it is enough that the positioning markers using for matching the position are formed at only one channel at the center, and the precise mounting can be performed by these positioning markers at the central channel. Therefore, the same pattern of positioning markers are formed every channel for matching positions at mounting is meaningless. Moreover, the area of the positioning markers is not bonded to the mounting substrate, therefore the bonding area decreases, disadvantages in heat radiation and bonding strength occur.

Moreover, at the anode side surface being the opposite side of the bonding surface (cathode side), the infrared rays transmitting windows recognizing the positioning markers must be provided. Consequently, a metal covered area (metal film) is decreased on the anode side surface, and when bonding wires are bonded to the anode side surface, the bonding surface becomes small. Therefore there is a problem that the mounting productivity becomes worse.

### SUMMARY OF THE INVENTION

It is therefore an object of the present invention to provide an array type laser diode and a manufacturing method thereof, in which positioning markers at adjacent channels are not needed except at a central channel, and regardless of the number of channels, the following effects can be realized at the same time; the stress lessening characteristic inside the laser diodes is improved, the bonding strength at the bonding is increased, the heat radiation performance of the laser diodes is increased, and the bonding wire mounting to the laser diode is made to be easy.

According to a first aspect of the present invention, for achieving the objects mentioned above, an array type laser diode, in which plural channels having a laser diode are provided in an array state, provides a central channel in which the designated number of conductive electrodes being cathode electrodes and the designated number of island shaped dielectric electrodes for stress lessening are formed, and plural channels except said central channel, in which the designated number of conductive electrodes being cathode electrodes and the designated number of island shaped dielectric electrodes for stress lessening are formed, at the both sides of said central channel in parallel. And only said central channel provides positioning markers for matching positions.

According to a second aspect of the present invention, an array type laser diode, in which plural channels having a laser diode are provided in an array state, provides a central channel that provides positioning markers which are used when a passive alignment technology is applied to form said array type laser diode, and plural channels except said central channel, whose pattern of conductive electrodes being cathode electrodes is formed in different size in each channel in order to make the connecting area at which an array substrate is connected to a mounting substrate large, at the both sides of said central channel in parallel.

According to a third aspect of the present invention in the first aspect, said central channel provides a positioning marker transmitting window, through which optical images of said positioning markers at said cathode side are transmitted, at an anode side being the opposite side of a cathode side at which said array substrate is connected to said mounting substrate.

According to a fourth aspect of the present invention in the first aspect, an area of said island shaped dielectric electrodes formed at said plural channels except said central channel becomes large corresponding to an area in which said positioning markers are not formed.

According to a fifth aspect of the present invention in the first aspect, a metal film is formed on the whole area of said anode side of said plural channels except said central channel.

According to a sixth aspect of the present invention, a manufacturing method of an array type laser diode, in which plural channels having a laser diode are provided in an array state, provides the steps of forming the designated number of conductive electrodes being cathode electrodes and the designated number of island shaped dielectric electrodes for stress lessening at a central channel, forming the designated number of conductive electrodes being cathode electrodes and the designated number of island shaped dielectric electrodes for stress lessening at plural channels provided at the both sides of said central channel, and forming positioning markers for matching positions at only said central channel.

According to a seventh aspect of the present invention, a manufacturing method of an array type laser diode, in which plural channels having a laser diode are provided in an array state, provides the steps of formimg positioning markers for matching positions only at a central channel when a passive alignment technology is applied to form said array type laser diode, and forming pattern of conductive electrodes being cathode electrodes in different size in each channel in order to make the connecting area at which an array substrate is connected to a mounting substrate large, at plural channels provided at the both sides of said central channel.

According to an eighth aspect of the present invention, in the sixth aspect, a manufacturing method of an array type laser diode further provides the step of forming a positioning marker transmitting window, through which optical images of said positioning markers at said cathode side are transmitted, at an anode side being the opposite side of a cathode side at which said array substrate is connected to said mounting substrate.

According to a ninth aspect of the present invention, in the sixth aspect, a manufacturing method of an array type laser diode further provides the step of forming an area of said island shaped dielectric electrodes providing at said plural channels except said central channel by making large corresponding to an area in which said positioning markers are not formed.

According to a tenth aspect of the present invention, in the sixth aspect, a manufacturing method of an array type laser diode further provides the step of forming a metal film on the whole area of said anode side of said plural channels except said central channel.

### BRIEF DESCRIPTION OF THE DRAWINGS

The objects and features of the present invention will become more apparent from the consideration of the following detailed description taken in conjunction with the accompanying drawings in which:

FIG. 1 is a diagram showing a pattern of cathode side electrodes bonding to a mounting substrate at a conventional array type laser diode;

FIG. 2 is a diagram showing a pattern of anode side electrodes at the conventional array type laser diode shown in FIG. 1;

FIG. 3 is a diagram showing a pattern of cathode side electrodes bonding to a mounting substrate at a central channel of an embodiment of an array type laser diode of the present invention;

FIG. 4 is a perspective view showing the cathode side of the central channel at the embodiment of the array type laser diode of the present invention;

FIG. 5 is a diagram showing a pattern of anode side electrodes of the central channel at the embodiment of the array type laser diode of the present invention;

FIG. 6 is a perspective view showing the anode side of the central channel at the embodiment of the array type laser diode of the present invention;

FIG. 7 is a perspective view showing the cathode side of channels except the central channel at the embodiment of the array type laser diode of the present invention; and

FIG. 8 is a perspective view showing a manufacturing method of the embodiment of the array type laser diode of the present invention.

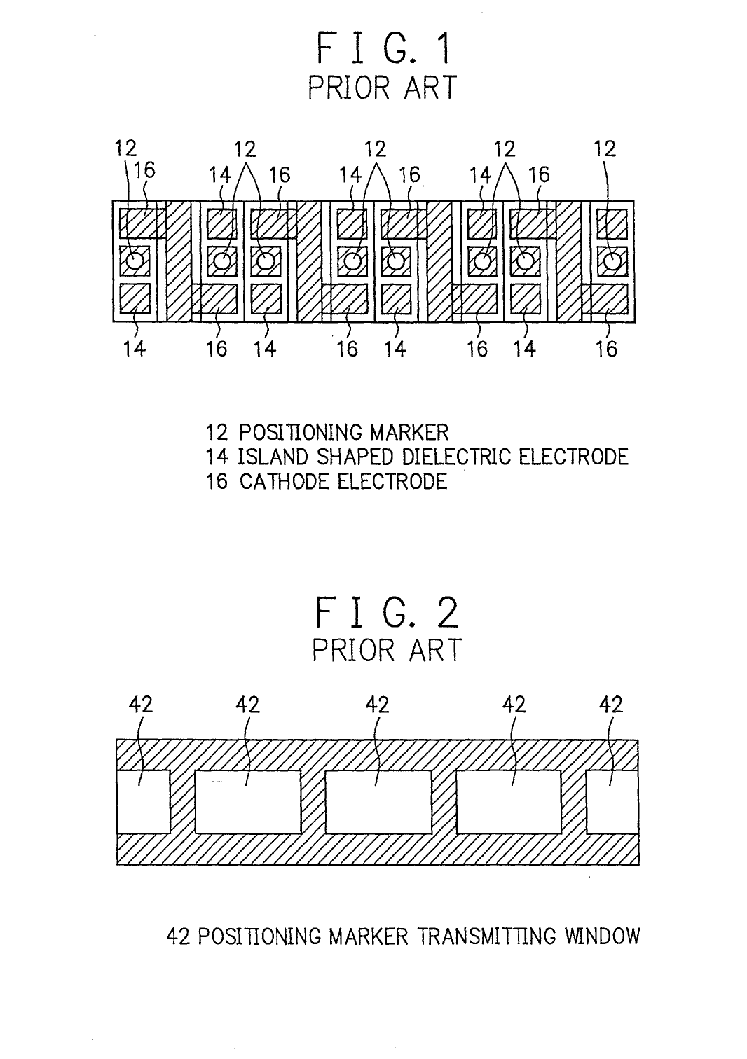

### DESCRIPTION OF THE PREFERRED EMBODIMENTS

Referring now to the drawings, an embodiment of the present invention is explained in detail. Recently, an optical communication technology used optical fiber has been utilized in order to realize an inter-connection technology. At this optical communication technology used the optical fiber, as a light source for the optical communication, the realization of an optical IC in which plural laser diodes are integrated has been required. There is an array type laser diode, as a representative of the optical IC in which plural laser diodes are integrated.

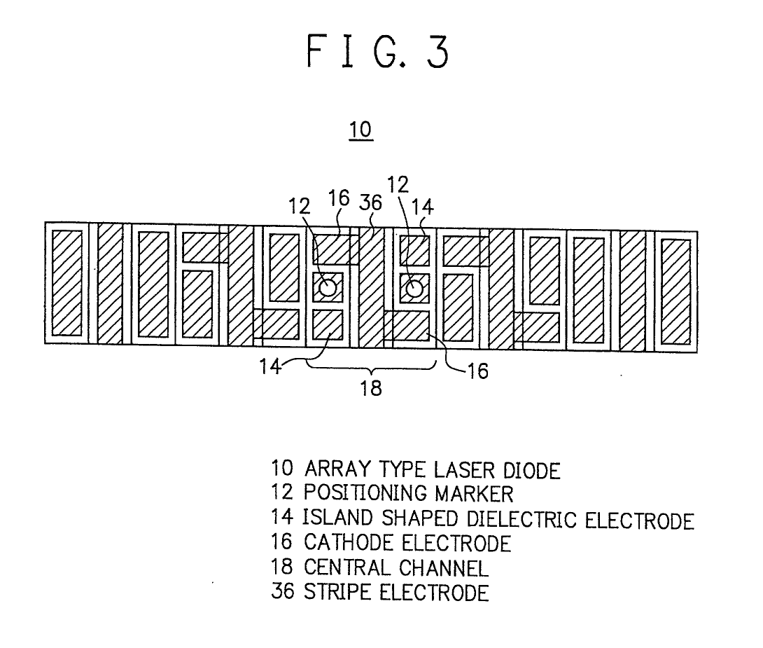

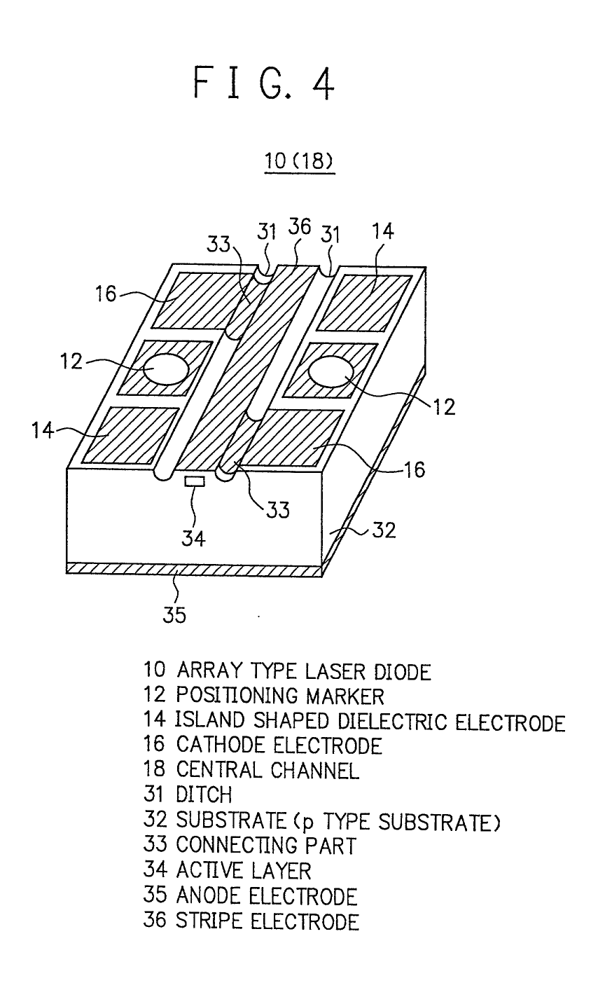

FIG. 3 is a diagram showing a pattern of cathode side electrodes bonding to a mounting substrate at a central channel of an embodiment of an array type laser diode of the present invention. FIG. 4 is a perspective view showing the cathode side of the central channel at the embodiment of the array type laser diode of the present invention.

At this embodiment, in order to make the explanation concise, the number of channels is set as three, but the number of channels is not limited to three, actually the number of channels is three or more.

First, referring to FIGS. 3 and 4, the structure of the central channel 18 of the array type laser diode 10 of the embodiment of the present invention is explained. At the central channel 18, two conductive electrodes (cathode electrodes) 16, two island shaped dielectric electrodes 14 for stress lessening, two positioning markers 12 are formed, positioned with a stripe electrode 36 between them.

Straight line shaped ditches 31 are formed at the both sides of the stripe electrode 36. Each of the two conductive electrodes (cathode electrodes) 16 is connected to the stripe electrode 36 via each of two connecting parts 33 formed on each of the surfaces of the ditches 31. An active layer 34 being a laser light source is embeded in a mesa type p type substrate 32 whose side faces are formed by these two ditches 31. The emitting direction (optical axis) of laser from the laser light source is equivalent to the stretching direction of the stripe electrode 36.

The stripe electrode 36 is formed on the upper surface (cathode side) of the mesa type p type substrate 32 whose side faces are formed by the two ditches 31.

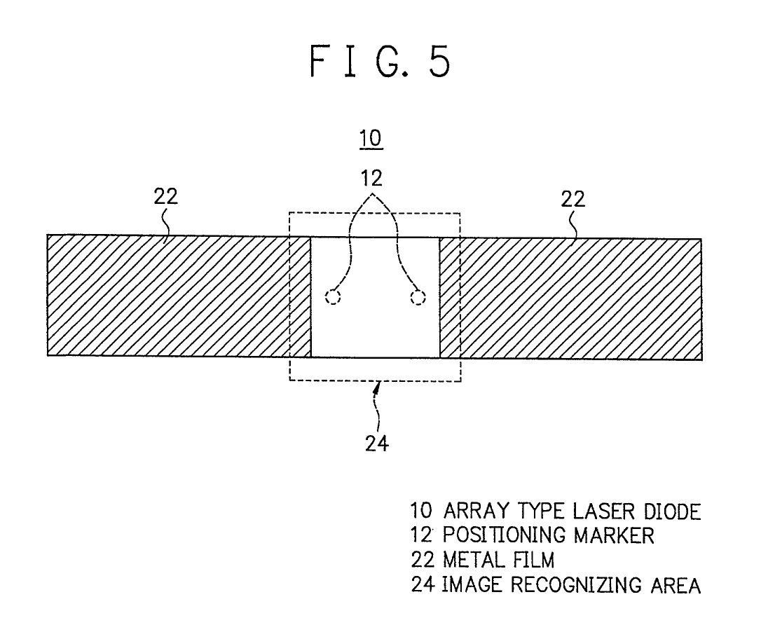

FIG. 5 is a diagram showing a pattern of anode side electrodes of the central channel at the embodiment of the array type laser diode of the present invention. As shown in FIG. 5, a window, whose size is the same as the central channel 18, for transmitting the positioning markers 12 is opened at a metal film 22 on the reverse surface (anode side) of the central channel 18 having an image recognizing area 24 in which an image recognition for positioning is performed.

As shown in FIG. 4, the pattern structure of the central channel 18 of the array type laser diode 10 of the present invention provides all of the cathode electrodes 16, the positioning markers 12 and the island shaped dielectric electrodes 14.

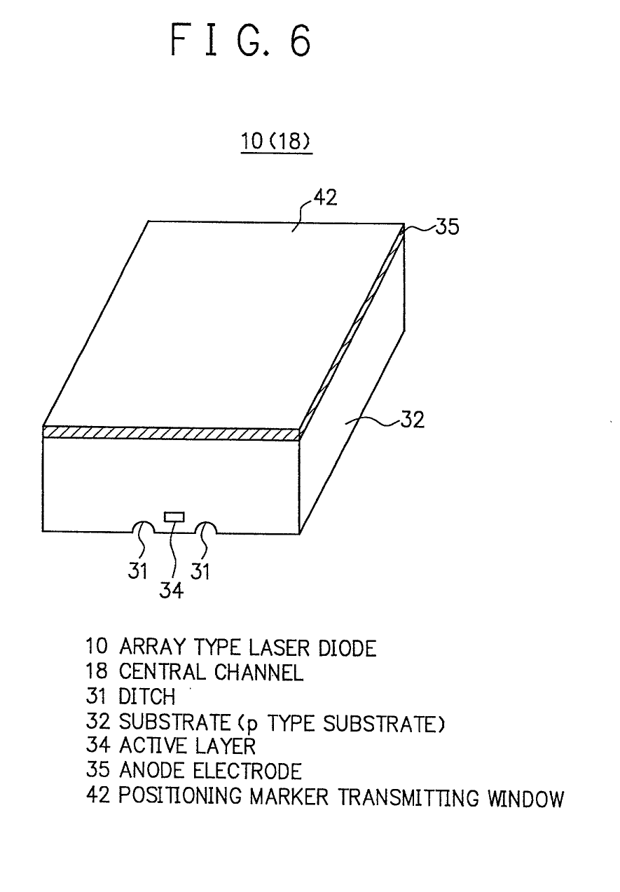

FIG. 6 is a perspective view showing the anode side of the central channel at the embodiment of the array type laser diode of the present invention. As shown in FIG. 6, on the anode side being the reverse side of the cathode side, the positioning marker transmitting window 42, through which the optical images of the positioning markers 12 of the cathode side are transmitted, is provided only at the part of the central channel 18.

That is, at the array type laser diode, regardless of the number of channels, the present invention provides the positioning markers 12 only at the central channel 18 and does not provide the positioning markers 12 at the adjacent channels 17 to the central channel 18. With this structure, when the passive alignment technology is applied to form the array type laser diode, electrode structure having higher bonding strength compared with the conventional array type laser diode can be realized. And the bonding area becomes larger, therefore, by this electrode structure, the heat radiation to the side of a mounting substrate on which the array type laser diode is mounted is increased. Moreover, by this electrode structure, bonding wires connecting to the mounting substrate at the upper surface (anode side) is made to be easy. As a result, the positioning markers 12 are not needed at the channels except the central channel 18, and regardless of the number of channels, the following characteristics can be realized at the same time; the stress lessening characteristic in the laser diodes is improved, the bonding strength at the wire bonding is increased and the heat radiation performance of the laser diodes is increased. Furthermore, an effect that the mounting of the bonding wires to the laser diode is made to be easy is realized.

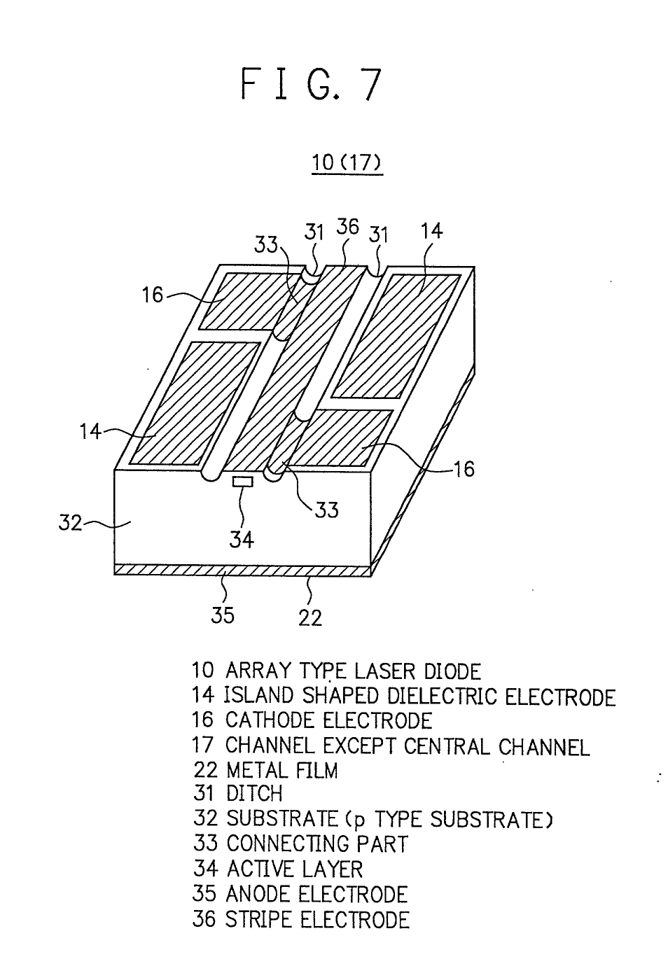

Next, the structure of channels 17 formed at the both sides of the central channel 18 of the array type laser diode 10 is explained. FIG. 7 is a perspective view showing the cathode side of channels except the central channel at the embodiment of the array type laser diode of the present invention. As shown in FIG. 7, the channels 17 formed at the both sides of the central channel 18 do not recognize the positioning markers 12 in the central channel 18, therefore two conductive electrodes (cathode electrodes) 16, two island shaped dielectric electrodes 14 for stress lessening are formed with the stripe electrode 36 between them. In this, the size of the island shaped dielectric electrodes 14 is larger than that at the central channel 18, because the positioning markers 12 are not formed at the channels 17.

Straight line shaped ditches 31 are formed at the both sides of the stripe electrode 36. As shown in FIG. 7, on the whole surface of the reverse side (anode side) of the channels 17, which are the channels except the central channel 18 having the image recognizing area 24, the metal film 22 for connecting wire bonding is formed.

That is, at the channels 17 except the central channel 18, the cathode electrodes 16 and the island shaped dielectric electrodes 14 are formed. And the island shaped dielectric electrodes 14 are larger-than those of the central channel 18, because the positioning markers 12 at the central channel 18 are not formed at the channels 17. On the anode side being the reverse side of the bonding surface (cathode side), the metal film 22 is formed on the whole surface at the channels 17.

Each of the two conductive electrodes (cathode electrodes) 16 is connected to the stripe electrode 36 via each of two bonding parts 33 formed on each of the surfaces of the ditches 31. The active layer 34 being a laser light source is embeded in the mesa type p type substrate 32 whose side faces are formed by these two ditches 31. The emitting direction (optical axis) of laser from the laser light source is equivalent to the stretching direction of the stripe electrode 36.

The stripe electrode 36 is formed on the upper surface (cathode side) of the mesa type p type substrate 32 whose side faces are formed by the two ditches 31. On the channels 17 except the central channel 18, the positioning markers 12 are not needed, therefore only the island shaped dielectric electrodes 14 for stress lessening, the cathode electrodes 16 and the stripe electrode 36 are formed.

With this structure, when the passive alignment technology is applied to form an array type laser diode, electrode structure having the same or higher bonding strength than the conventional array type laser diode can be realized. And the bonding area becomes larger, therefore the electrode structure, by which the heat radiation to the side of the mounting substrate on which the array type laser diode is mounted is increased, can be realized. Moreover, by this electrode structure, bonding wires connecting to the mounting substrate at the upper surface (anode side) is made to be easy. As a result, the bonding strength increases by widening the bonding area, and the heat radiation performance of the laser diodes is largely improved. And mounting the bonding wires to the array type laser diode becomes easy.

Regardless of the number of channels, the positioning markers 12 are formed only at the central channel 18 and not formed at the channels 17, therefore the stress lessening characteristic, bonding strength and heat radiation performance are improved.

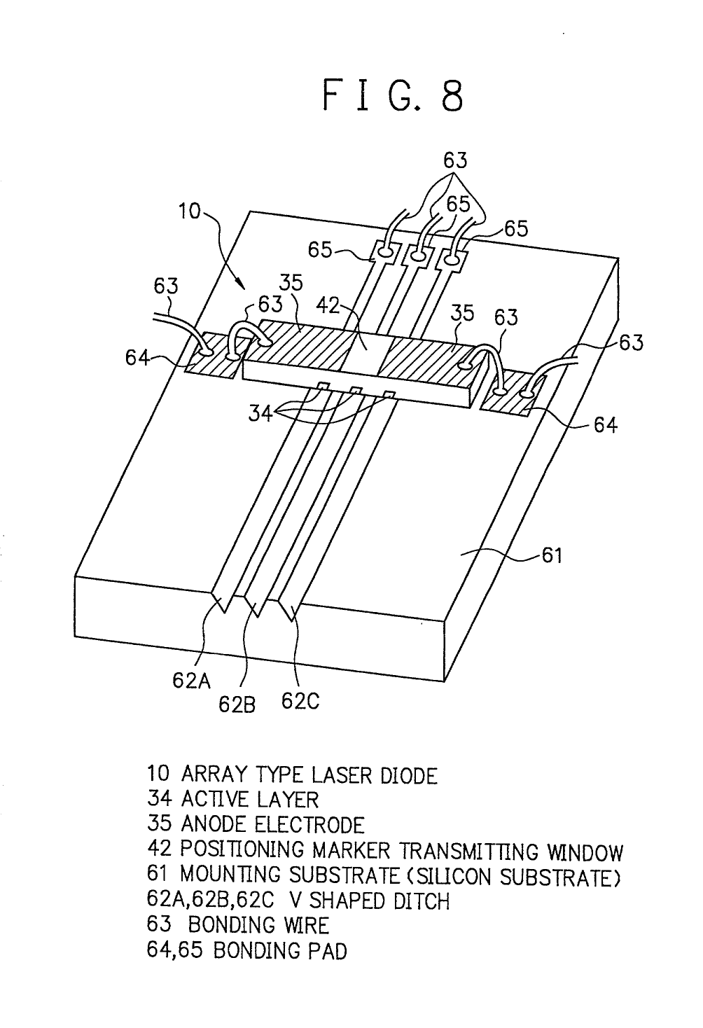

FIG. 8 is a perspective view showing a manufacturing method of the embodiment of the array type laser diode of the present invention.

The manufacturing method of the array type laser diode 10, in which plural channels having a laser diode are provided in array state, provides a process that forms the designated number of conductive electrodes (cathode electrodes) 16 and the designated number of island shaped dielectric electrodes 14 for stress lessening at the central channel 18, a process that forms the designated number of conductive electrodes (cathode electrodes) 16 and the designated number of island shaped dielectric electrodes 14 for stress lessening at the channels 17 positioned in parallel at the both sides of the central channel 18, and a process that forms positioning markers 12 using for matching positions at only the central channel 18.

In other words, when the passive alignment technology is applied to form the array type laser diode 10, the manufacturing method of the array type laser diode 10 provides a process that forms positioning markers 12 using for matching positions at only the central channel 18, and a process that forms the pattern of the conductive electrodes (cathode electrodes) 16 in different size every channel of the channels 17 positioned in parallel at the both sides of the central channel 18, in order to make the bonding area of the substrate connecting to the mounting substrate wide.

The manufacturing method of the array type laser diode 10 further provides a process that forms a positioning marker transmitting window 42, at the anode side being the opposite side of the cathode side that is the connecting surface for mounting the array type laser diode 10 to the mounting substrate, in order to transmit optical images of the positioning markers 12 at the cathode side, a process that makes the area of the island shaped dielectric electrodes 14 larger corresponding to the area eliminated the positioning markers 12 when the cathode electrodes 16 and the island shaped dielectric electrodes 14 are formed at the channels 17 except the central channel 18, and a process that forms a metal film on the whole surface of the anode side at the channels 17 except the central channel 18.

As shown in FIG. 8, on a mounting substrate (silicon substrate) 61, three straight line shaped ditches 62A, 62B and 62C, whose cross section is V shaped, are formed in parallel. The array type laser diode 10 of the embodiment of the present invention is mounted on the silicon substrate 61, at a state that the cathode side of the array type laser diode 10 is made to be downward direction. In this, the active layer 34 of the central channel 18 is positioned at the center of the ditch 62B, and the active layers 34 of the channels 17 at the both sides of the central channel 18 are positioned at the centers of the ditches 62A and 62C respectively. At the embodiment of the array type laser diode 10 of the present invention, the central channel 18 is used for positioning the array type laser diode 10 at mounting to the silicon substrate 61.

The cathode electrodes 16 of the central channels 18 and the channels 17 at the both sides of the central channel 18 are connected to bonding pads 65 in one to one respectively. The bonding pads 65 are connected to external terminals, for example, output terminals of a driving device (not shown), via bonding wires 63 respectively.

As shown in FIG. 8, the anode electrodes 35 at the both sides of the central channel 18 are connected to bonding pads 64 via bonding wires 63 respectively.

At this mounting state, when a driving signal is applied to the anode electrodes 35 and the cathode electrodes 16 of the central channel 18, a laser beam is emitted from the active layer 34 (laser light source) of the central channel 18. As the same as mentioned above, when a driving signal is applied to the anode electrodes 35 and the cathode electrodes 16 of the channels 17 at the both sides of the central channel 18, laser beams are emitted from the active layers 34 (laser light sources) of the channels 17. The emitting directions (light axes) of the laser beams are the same as the stretching directions of the V shaped ditches 62A, 62B and 62C.

As mentioned above, at the embodiment of the array type laser diode 10 of the present invention, regardless of the number of channels, the positioning markers 12 are provided at only the central channel 18 and are not provided at the adjacent channels 17 except the central channel 18. In this structure, the positioning markers 12 are not necessary at the adjacent channels 17 of the central channel 18. In order to apply the passive alignment technology based on the image recognition, the positioning markers 12 are provided only at the central channel 18, at the process that the laser diodes are mounted on the mounting substrate (silicon substrate) 61 by using the Au Sn solder, the thermal stress applied to the active layers 34 during the state from heated to the melting point of the solder to the ambient temperature is made to be as small as possible, and the bonding strength after bonded is related to the bonding area, therefore, in order to strengthen the bonding strength, the bonding area can be large. Moreover, the heat generated by the laser diodes themselves, when the laser diodes are driven, can be efficiently flown to the mounting substrate 61.

As mentioned above, regardless of the number of channels, at the embodiment of the present invention, the following improvements of characteristics are realized at the same time. That is, the stress lessening characteristic inside the laser diodes can be improved, and the bonding strength at the wire bonding can be increased, and the heat radiation performance of the laser diodes can be increased. Moreover, mounting the bonding wires 63 between the laser diodes and the mounting substrate is made to be easy.

The embodiment of the present invention is not limited to the array type laser diode and the manufacturing method thereof. The present invention can be applied for an optical IC with which an optical information processing such as an optical communication and an optical recording employing a light source such as laser diodes is performed. And the number, position and shape of constituting components mentioned above are not limited to the embodiment mentioned above, the suitable number, position and shape of components can be used in any application. And the same components and functions in the embodiment of the present invention and the conventional example have the same reference number in each drawing.

As mentioned above, at the embodiment of the array type laser diode 10 of the present invention, regardless of the number of channels, the positioning markers 12 are provided at only the central channel 18 and are not provided at the adjacent channels 17 to the central channel 18. In this structure, the positioning markers 12 are not necessary at the adjacent channels 17 to the central channel 18. And regardless of the number of channels, the following improvements of characteristics are realized at the same time. That is, the stress lessening characteristic inside the laser diodes can be improved, and the bonding strength at the wire bonding can be increased, and the heat radiation performance of the laser diodes can be increased. Moreover, mounting the bonding wires 63 between the laser diodes and the mounting substrate is made to be easy.

While the present invention has been described with reference to the particular illustrative embodiments, it is not to be restricted by those embodiments but only by the appended claims. It is to be appreciated that those skilled in the art can change or modify the embodiments without departing from the scope and spirit of the present invention.

What is claimed is:

1. An array type laser diode, in which plural channels having a laser diode are provided in an array state, comprising:
a central channel that provides positioning markers which are used when a passive alignment technology is applied to form said array type laser diode, and
plural channels except said central channel, whose pattern of conductive electrodes being cathode electrodes is formed in different size in each channel in order to make the connecting area at which an array substrate is connected to a mounting substrate large, at the both sides of said central channel in parallel.

2. An array type laser diode in accordance with claim 1, wherein:
said central channel provides a positioning marker transmitting window, through which optical images of said positioning markers at said cathode side are transmitted, at an anode side being the opposite side of a cathode side at which said array substrate is connected to said mounting substrate.

3. An array type laser diode in accordance with claim 1, wherein:
a metal film is formed on the whole area of said anode side of said plural channels except said central channel.

4. A manufacturing method of an array type laser diode, in which plural channels having a laser diode are provided in an array state, comprising the steps of:
forming positioning markers for matching positions only at a central channel when a passive alignment technology is applied to form said array type laser diode, and
forming pattern of conductive electrodes being cathode electrodes in different size in each channel in order to make the connecting area at which an array substrate is connected to a mounting substrate large, at plural channels provided at the both sides of aid central channel.

5. A manufacturing method of an array type laser diode in accordance with claim 4, further comprising the step of:
forming a positioning marker transmitting widow, through which optical images of said positioning markers at said cathode side are transmitted, at an anode side being the opposite side of a cathode side at which said array substrate is connected to said mounting substrate.

6. A manufacturing method of an array type laser diode in according with claim 4, further comprising the step of:
forming a metal film on the whole area of said anode side of said plural channels except said central channel.
